(19) United States
(12) Patent Application Publication
(10) Pub. No.: US 2004/0062093 A1
(43) Pub. Date: Apr. 1, 2004

(54) Data writing apparatus, data writing/reading apparatus, data writing method and data writing/reading method

(75) Inventor: Hajime Harashima, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: NEC CORPORATION

(21) Appl. No.: 10/664,890

(22) Filed: Sep. 22, 2003

(30) Foreign Application Priority Data
Oct. 1, 2002 (JP) 289071/2002

(51) Int. Cl. G11C 7/00

(52) U.S. Cl. 365/200

(57) ABSTRACT

Disclosed are a data writing apparatus and a data writing/reading apparatus which can allow an upper-rank unit to properly complete data writing and reading when a double failure occurs, reads data from an address at which a failure has occurred during data correction at that address and completes writing data in a hard disk device when correction of data at the address at which the failure has occurred is completed. When data writing at a logical address of a logical disk is disabled due to a double failure, logical disk writing/reading means writes the data in a memory and reports proper completion of writing to an upper-rank unit. The upper-rank unit reads the data from the memory. When reported from write-enableness reporting means that writing at the logical address becomes enabled, the logical disk writing/reading means writes the data in the memory at the logical address of the logical disk.

### BACKGROUND OF THE INVENTION

1. Field of the Invention

The present invention relates to a data writing apparatus, a data writing/reading apparatus, a data writing method and a data writing/reading method. More particularly, the invention relates to a data writing apparatus, a data writing/reading apparatus, a data writing method and a data writing/reading method which can cope with a case where redundancy destruction occurs in a memory device having a redundancy structure.

2. Description of the Related Art

There is a disk array apparatus as a conventional data writing apparatus.

FIG. 10 is a block diagram of a conventional disk array apparatus showing the structures of an upper-rank unit 100, a controller 1101 and a logical disk 120.

To execute data writing/reading with respect to the logical disk 120, the upper-rank unit 100 sends a write command for data to the controller 1101 and transfers the data to the controller 1101 in case of data writing, or sends a read command for data to the controller 1101 and receives the data from the controller 1101 in case of data reading.

The controller 1101 has logical disk monitoring means 111 and logical disk writing/reading means 112.

The logical disk monitoring means 111 has management table updating means 150 and a timer 114. With the timer 114 powered on, the timer 114 regularly informs the management table updating means 150 of the passage of a given time. When informed from the timer 114 that a given time has elapsed, the management table updating means 150 monitors the status of each logical address in the logical disk 120. Then, the management table updating means 150 checks the status of the logical disk 120 in a synchronism with the upper-rank unit 100.

Upon reception of a data write command and data from the upper-rank unit 100, the logical disk writing/reading means 112 writes data at the logical address in the logical disk 120 which is designated by the upper-rank unit 100. When writing is not possible, a retry is performed a specified number of times. When even the specified number of retries cannot complete writing, the logical disk writing/reading means 112 reports a writing error to the upper-rank unit 100. When writing is completed, the logical disk writing/reading means 112 reports completion of proper writing to the upper-rank unit 100. When writing could not be completed, the logical disk writing/reading means 112 reports a writing error to the upper-rank unit 100.

Upon reception of a data read command and data from the upper-rank unit 100, the logical disk writing/reading means 112 reads data from the logical address in the logical disk 120 which is designated by the upper-rank unit 100. When reading is not possible, a retry is performed a specified number of times. When even the specified number of retries cannot complete reading, the logical disk writing/reading means 112 reports a reading error to the upper-rank unit 100. When reading is completed, the logical disk writing/reading means 112 reports completion of proper reading to the upper-rank unit 100. When reading could not be completed, the logical disk writing/reading means 112 reports a reading error to the upper-rank unit 100.

The logical disk 120 has a plurality of HDDs (in this example, there are five HDDs 130A to 130E). When the logical disk 120 receives a data write command from the controller 1101, data is written with redundancy at a logical address designated by the controller 1101. In this example, it is illustrated that data is written at a logical address 140A. When the logical disk 120 receives a data read command from the controller 1101, data is read from a logical address designated by the controller 1101. In this example, it is illustrated that data is read from the logical address 140A.

Here, the logical disk 120 is in such a state as to have a medium error at the logical address 140A in the HDD 130E. The HDD 130A is in a state where data repairing is taking place after replacement of an HDD due to a disk failure. Accordingly, the logical address 140A is in a double failure state to be inaccessible so that writing at that address is not possible. Likewise, data cannot be read from the logical address 140A.

While only the HDD 130A is undergoing data repairing, the HDD 130E has no medium error at a logical address 140B so that both writing and reading can be performed in the HDD 130E.

FIG. 11 is a flowchart illustrating the operation of the conventional disk array apparatus equipped with the upper-rank unit 100, the controller 1101 and the logical disk 120 at the time the upper-rank unit 100 writes data in the logical disk 120.

When the upper-rank unit 100 sends data to be written in the logical disk 120 to the controller 1101 (step P1), the logical disk writing/reading means 112 in the controller 1101 receives the write data (step P2). Next, the logical disk writing/reading means 112 writes the data at a logical address in the logical disk 120 which is designated by the upper-rank unit 100. In this example, data writing is performed at the logical address 140A. When writing is not possible then, a retry is performed a specified number of times. When writing at the logical address 140A is completed in any one of the first retry to the last one in the specified number of retries (Y in step P3), the logical disk writing/reading means 112 reports completion of proper writing to the upper-rank unit 100 (step P4). When writing at the logical address 140A could not be completed through the specified number of retries (N in step P3), the logical disk writing/reading means 112 reports a writing error to the upper-rank unit 100 (step P5).

FIG. 12 is a flowchart illustrating the operation of the conventional disk array apparatus equipped with the upper-rank unit 100, the controller 1101 and the logical disk 120 at the time the upper-rank unit 100 reads data from the logical disk 120.

When the upper-rank unit 100 receives a read command to read data from the logical disk 120 to the controller 1101 (step Q1), the logical disk writing/reading means 112 in the controller 1101 receives the read command (step Q2). Next, the logical disk writing/reading means 112 reads data from the logical address 140A in the logical disk 120 which is designated by the upper-rank unit 100. When reading is not possible then, a retry is performed a specified number of times. When reading from the logical address 140A is completed in-any one of the first retry to the last one in the specified number of retries (Y in step Q3), the logical disk writing/reading means 112 transfers read data to the upper-rank unit 100 (step Q4). When reading from the logical address 140A could not be completed through the specified number of retries (N in step Q3), the logical disk writing/reading means 112 reports a reading error to the upper-rank unit 100 (step Q5).

The operation of the logical disk monitoring means 111 will be discussed below. FIG. 13 is a flowchart illustrating the operation of the logical disk monitoring means 111. When the controller 1101 is powered on, the timer 114 starts measuring the time. When a given time elapses, the timer 114 informs the management table updating means 150 of the event (step R1). The management table updating means 150 checks the status of the logical disk 120 and updates a management table 151 based on the status (step R2). The timer 114 keeps operating as long as the controller 1101 is powered on. The operation of the logical disk monitoring means 111 is performed in a synchronism with the operation of the upper-rank unit 100.

A description will now be given of the operation of the conventional disk array apparatus in the flowchart in FIG. 11 when logical disk 120 has a double failure in the HDD 130A and HDD 130E in the block diagram in FIG. 10. The logical disk 120 is in such a state as to have a medium error at the logical address 140A in the HDD 130E. The HDD 130A is in a state where data repairing is taking place after replacement of an HDD due to a disk failure. Accordingly, the logical address 140A is in a double failure state to be inaccessible so that writing at that address is not possible. Therefore, writing at the logical address 140A could not be completed even through a specified number of retries (N in step P3). Then, the logical disk writing/reading means 112 reports a writing error to the upper-rank unit 100 (step P5).

When a double failure temporarily occurs in an HDD, the disk array apparatus cannot write data in a part of the HDD from the upper-rank unit. Because the data cannot be read as a consequence, a possibility of causing an I/O error in which case a writing error or a reading error is reported to the upper-rank unit becomes higher (step P5 in FIG. 11). When an I/O error occurs, it is necessary to perform additional works of, for example, specifying the cause and rewriting data. This interferes with the normal work.

As a countermeasure against such a double failure, some of the conventional disk array apparatuses have double parity data to recover from the double failure (see, for example, Japanese Patent Laid-Open No. 2000-39970).

In a disk array apparatus which employs an ordinary write cache system, the probability of occurrence of an I/O error may be reduced by reporting proper completion of writing to an upper-rank unit at the point of time when data from the upper-rank unit is temporarily stored in a write cache.

The operation will be described referring to FIGS. 10 and 11. The logical disk writing/reading means 112 in FIG. 10 has a write cache. The “reporting of proper completion of writing to an upper-rank unit at the point of time when data from the upper-rank unit is temporarily stored in a write cache” is equivalent to reporting of proper completion of writing to the upper-rank unit 100 at the time the logical disk writing/reading means 112 in the controller 1101 has received write data. Then, reading the data which is having a double failure is carried out from the write cache. After repairing of the HDD that is currently having a failure is completed, the data from the write cache is written in the HDD to thereby save a data access at the time a double failure occurs. This may result in a case where the possibility of occurrence of an I/O error is reduced. The above-described scheme may however raise the following shortcomings.

The first shortcoming is that the saving scheme using the write cache should always have the write cache set in an enabled state. Normally, the write cache in such a disk array apparatus can be set ON and OFF, and even if the write cache is set ON (enabled), the write cache is often forcibly set OFF (disabled) depending on the operational status of each resource in the disk array apparatus at the time such as the occurrence of a failure. In this case, data cannot be temporarily saved in the write cache, so that when a double failure occurs temporarily in an HDD, writing and reading to and from the HDD cannot be carried out, resulting in an I/O error.

The second shortcoming is that even with the write cache enabled, data writing cannot be performed in some case, resulting in an I/O error. When data in a logical disk is being repaired, after write data from the upper-rank unit is temporarily saved in the write cache, writing of data to the logical disk is started one data after another. When data writing has resulted in an error at the time a double failure temporarily occurs in an HDD, data writing can be done through a retry operation if the repairing of the target address in the HDD which undergoes data repairing during a specified number of retries. When the repairing of the target address in the HDD which undergoes data repairing cannot be completed during the retries, writing of data from the write cache cannot be done, resulting in an I/O error. When the logical disk is in the reduced state, a double failure always occurs at the address portion so that retry-oriented writing is not possible. As in the previous case, writing of data from the write cache cannot be done, resulting in an I/O error.

In the disk array apparatus using the write cache, when writing of data from the upper-rank unit is completed, the controller may report proper completion of writing to the upper-rank unit. Even when writing of data to an HDD from the write cache cannot be done after the reporting of the proper completion of writing, an I/O error has not occurred as seen from the upper-rank unit. This is however tantamount to writing at the address in the HDD having not been done, so that data cannot be read from the address in the HDD.

### SUMMARY OF THE INVENTION

An object of the present invention is to provide a data writing apparatus and a data writing/reading apparatus which can allow an upper-rank unit to properly complete data writing and data reading at the time a double failure occurs.

Another object of the present invention is to provide a data writing apparatus and a data writing/reading apparatus which can read data at an address where a failure has occurred even during data repairing at that address.

A further object of the present invention is to provide a data writing apparatus and a data writing/reading apparatus which can complete writing to an HDD when data repairing at an address where a failure has occurred is completed.

A data writing/reading apparatus according to the invention comprises an upper-rank unit, first storage means where data to be written has a redundancy structure, and a control unit which writes data in the first storage means in response to a command from the upper-rank unit. The “redundancy structure” means the structure that allows the first storage means to include data writing of which is instructed by the upper-rank unit and redundancy data and, if data of a size equal to or smaller than a size of the redundancy data is destroyed, to ensure data writing from remaining data while repairing the data writing of which is instructed, in response to a command from the upper-rank unit. When a redundancy destruction occurs at an address in the first storage means, the control unit writes in the second storage means data writing of which at the address is instructed by the upper-rank unit. The control unit includes logical disk writing/reading means that reports completion of writing to the upper-rank unit and reads from the second storage means data for which a command to read from the address is given from the upper-rank unit when that data exists. At this time, the second storage means retains data written by the control unit until the data is read by the control unit.

That is, when writing of data at the target logical address is not possible, the data is written (or saved) in a memory and proper completion of writing is reported to the upper-rank unit. When reading of data from the target logical address is not possible, the saved data is read from the memory. Even when a double failure occurs, therefore, the upper-rank unit can properly complete data writing and data reading and avoid an I/O error.

For the same reason, data whose writing is commanded can be written even when a double failure occurs.

Further, in the data writing/reading apparatus, the control unit further comprises logical disk monitoring means which verifies if the redundancy destruction at the address has been recovered. When the logical disk monitoring means verifies that the redundancy destruction at the address has been recovered, the logical disk writing/reading means reads data written in the second storage means and writes the data at the address in the first storage means.

The logical disk monitoring means comprises management table updating means which checks a status of the first storage means and updates a management table; a timer which informs the management table updating means of passage of a given time when elapsed; and write-enableness reporting means which reports recovery of the redundancy destruction at the address to the logical disk writing/reading means when the management table indicates the recovery of the redundancy destruction.

Therefore, data can be written in an HDD immediately after repairing of a logical address where a failure has occurred is completed.

Further, the second storage means is non-volatile storage means or volatile storage means having an independent power supply.

Even when power is cut off at the time an HDD is removed from the logical disk, the upper-rank unit can properly complete data writing and data reading. It is also possible to read data from the address where a failure has occurred even during repairing of the address so that writing to the HDD can be completed when repairing of the failure-occurred address is completed.

### BRIEF DESCRIPTION OF THE DRAWINGS

The novel features believed characteristic of the invention are set forth in the appended claims. The invention itself, however, as well as other features and advantages thereof, will be best understood by reference to the detailed description which follows, read in conjunction with the accompanying drawings, wherein:

FIG. 1 is a block diagram showing the structures of an upper-rank unit 100, a controller 110 and a logical disk 120 according to a first embodiment of the present invention;

FIG. 2 is a flowchart illustrating the operations of the upper-rank unit 100, the controller 110 and the logical disk 120 according to the first embodiment of the invention at the time the upper-rank unit 100 writes data in the logical disk 120;

FIG. 3 is a block diagram showing the structures of the upper-rank unit 100, the controller 110 and the logical disk 120 according to the first embodiment of the invention and illustrating that repairing of data up to a logical address 140A in an HDD 130A in the logical disk 120 which is operating in a synchronism with the operation of the upper-rank unit 100 is completed and a double failure at the logical address 140A in the HDD 130A and an HDD 130E has been eliminated;

FIG. 4 is a flowchart illustrating the operations of the upper-rank unit 100, the controller 110 and the logical disk 120 according to the first embodiment of the invention at the time the upper-rank unit 100 reads data from the logical disk 120;

FIG. 5 is a general view of management table updating means 150;

FIG. 6 is a diagram showing the details of information on the logical address 140A;

FIG. 7 is a diagram showing the details of information on a logical address 140B;

FIG. 8 is a flowchart illustrating the operation of logical disk monitoring means 111;

FIG. 9 is a block diagram showing the structures of an upper-rank unit 100, a controller 110 and a logical disk 120 according to a second embodiment of the invention and illustrating that an HDD 130A is removed from the logical disk 120;

FIG. 10 is a block diagram showing the structures of a conventional upper-rank unit 100, controller 1101 and logical disk 120;

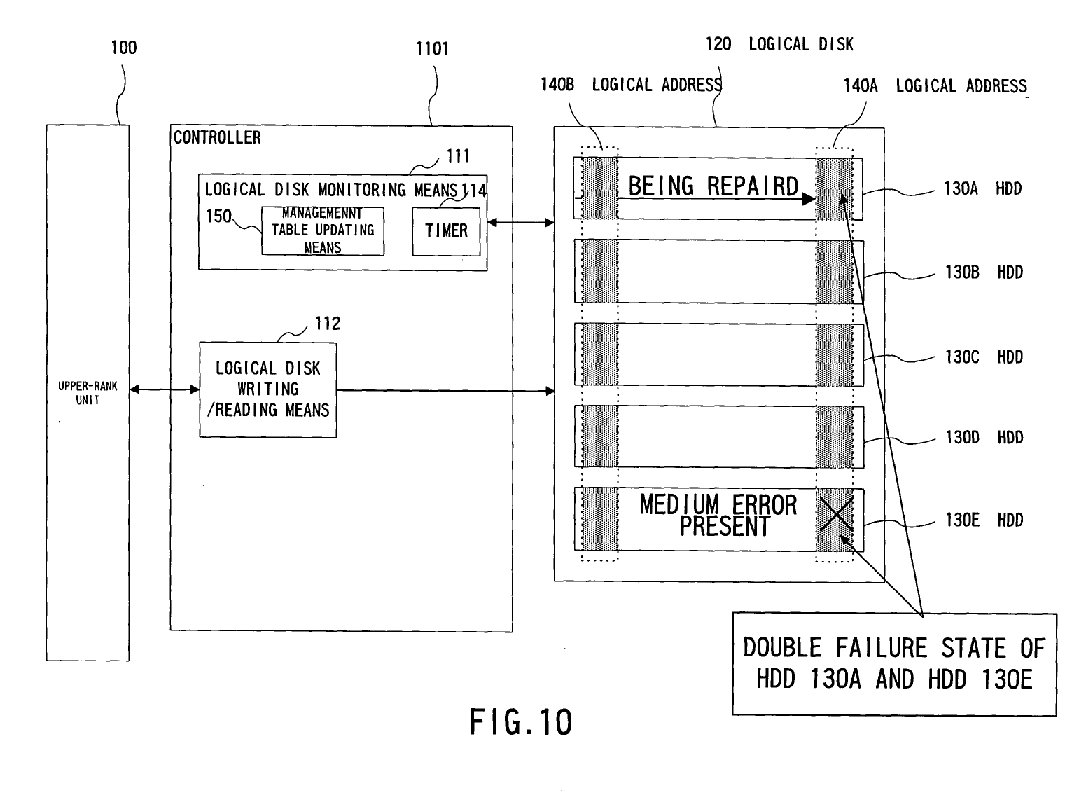

FIG. 11 is a flowchart illustrating the operation of a conventional disk array apparatus equipped with the upper-rank unit 100, the controller 1101 and the logical disk 120 at the time the upper-rank unit 100 writes data in the logical disk 120;

FIG. 12 is a flowchart illustrating the operation of the conventional disk array apparatus equipped with the upper-rank unit 100, the controller 1101 and the logical disk 120 at the time the upper-rank unit 100 reads data from the logical disk 120; and

FIG. 13 is a flowchart illustrating the operation of conventional logical disk monitoring means 111.

### DESCRIPTION OF THE PREFERRED EMBODIMENTS

The first embodiment of the present invention will now be described with reference to the accompanying drawings.

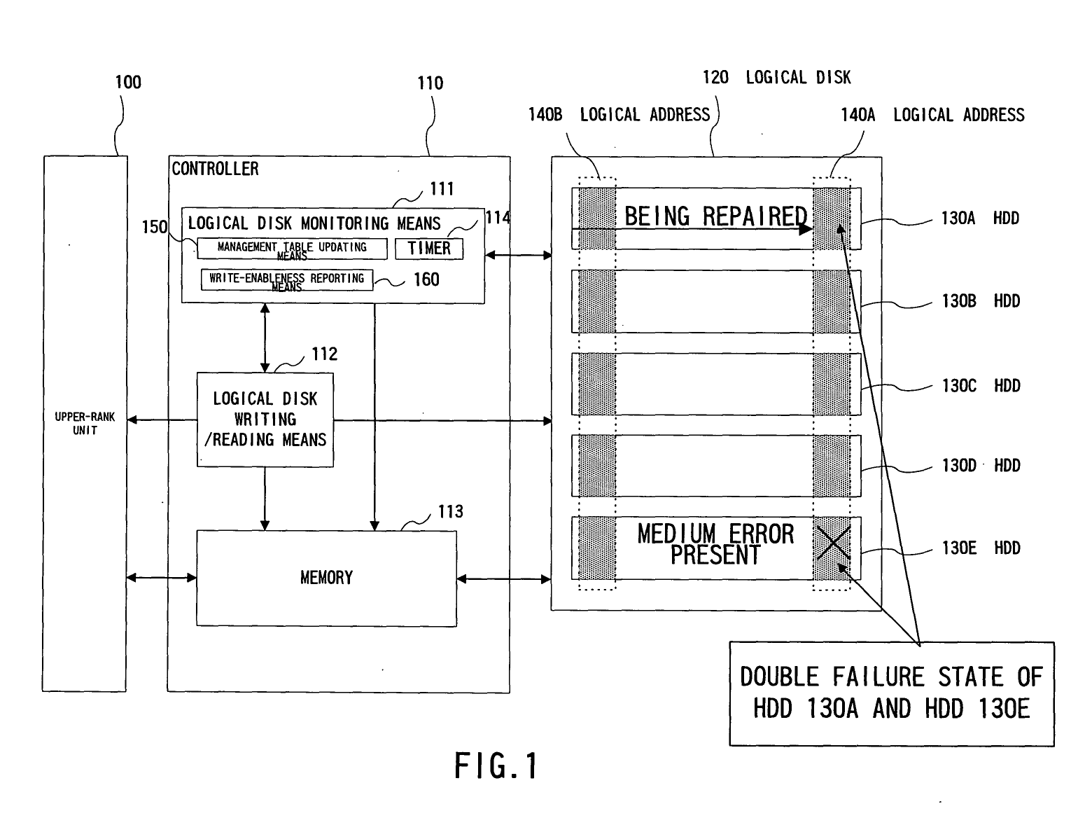

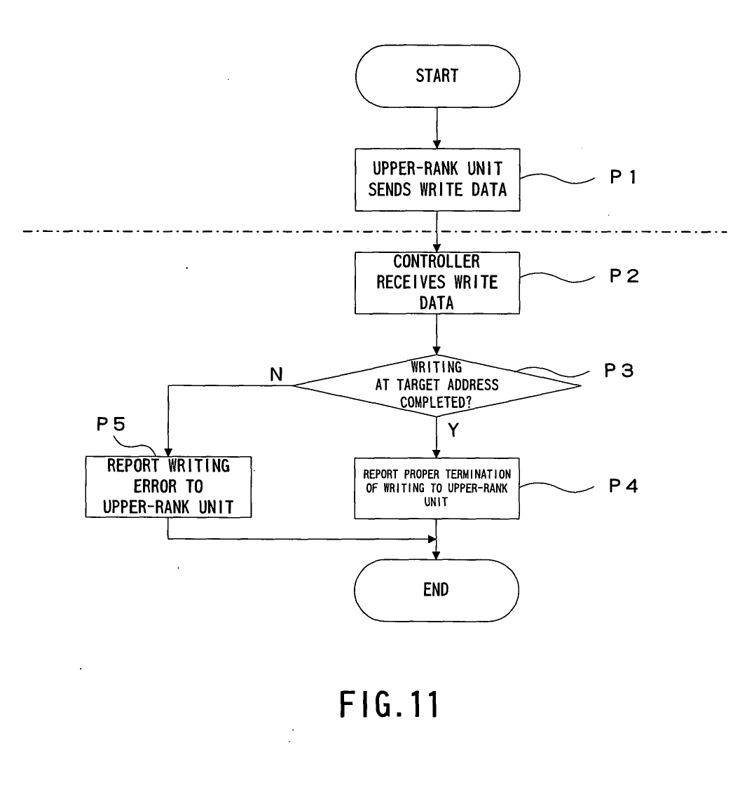

FIG. 1 is a block diagram showing the structures of an upper-rank unit 100, a controller 110 and a logical disk 120 according to the first embodiment of the invention. The first embodiment differs from the conventional disk array apparatus shown in FIG. 11 in that the controller 110 has a memory 113 and logical disk monitoring means 111 has write-enableness reporting means 160.

To execute data writing/reading with respect to the logical disk 120, the upper-rank unit 100 sends a write command for data to the controller 110 and transfers the data to the controller 110 in case of data writing. In case of data reading, the upper-rank unit 100 sends a read command for data to the controller 110 and receives the data from the controller 100. The upper-rank unit 100 receives a report on proper completion of writing, a report on a writing error and a report on a reading error from the controller 110. Upon reception of the report on proper completion of writing, the upper-rank unit 100 properly completes writing of the data.

The controller 110 has the logical disk monitoring means 111, logical disk writing/reading means 112 and the memory 113.

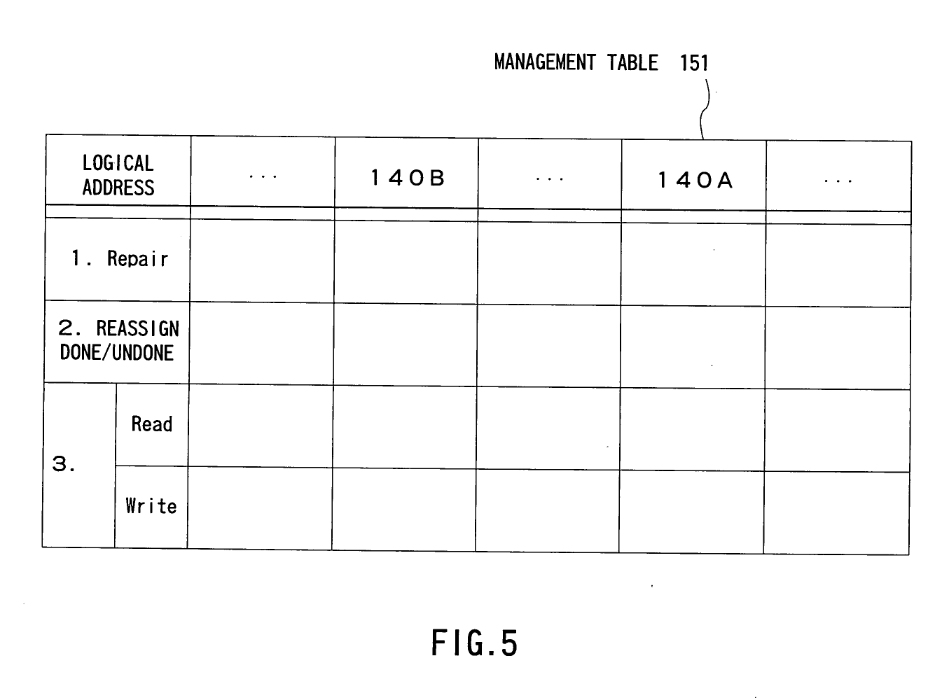

The logical disk monitoring means 111 has a timer 114, management table updating means 150 and the write-enableness reporting means 160. With the timer 114 powered on, the timer 114 regularly informs the management table updating means 150 of the passage of a given time. The management table updating means 150 checks the status of the logical disk 120 in a synchronism with the operation of the upper-rank unit 100. The management table updating means 150 has a management table 151 (see FIG. 5) and updates the management table 151 occasionally in accordance with the status of the logical disk 120.

When informed of a logical address writing at which by the logical disk writing/reading means 112 could not be performed, the write-enableness reporting means 160 always refers to the management table 151. When the logical address writing at which by the logical disk writing/reading means 112 has failed, i.e., the logical address 140A in the embodiment, comes to a state of Reassign OK (substitution OK which indicates that a double failure has been eliminated), the write-enableness reporting means 160 informs the logical disk writing/reading means 112 of that writing has become possible at the logical address writing at which by the logical disk monitoring means 111 has failed. The management table 151 will be discussed later.

Upon reception of a data write command and data from the upper-rank unit 100, the logical disk writing/reading means 112 writes data at the logical address in the logical disk 120 which is designated by the upper-rank unit 100. When writing is not possible, a retry is performed a specified number of times. When writing is completed, the logical disk writing/reading means 112 reports proper completion of writing to the upper-rank unit 100. When even the specified number of retries cannot complete writing, the logical disk writing/reading means 112 writes the data in the memory 113. Then, the logical disk writing/reading means 112 informs the write-enableness reporting means 160 of the logical address writing at which has failed and reports proper completion of writing to the upper-rank unit 100. When informed from the write-enableness reporting means 160 that the logical address writing at which by the logical disk writing/reading means 112 has failed, i.e., the logical address 140A in the embodiment, comes to a state of Reassign OK (substitution OK which indicates that a double failure has been eliminated), the logical disk writing/reading means 112 writes data in the memory 113 at the logical address 140A in the logical disk 120 where writing has been attempted.

Upon reception of a data read command and data from the upper-rank unit 100, the logical disk writing/reading means 112 reads data from the logical address in the logical disk 120 which is designated by the upper-rank unit 100 or the logical address 140A in the embodiment. When reading is not possible, a retry is performed a specified number of times. When reading is completed, the logical disk writing/reading means 112 transfers the read data to the upper-rank unit 100. When even the specified number of retries cannot complete reading, the logical disk writing/reading means 112 determines whether the data is written in the memory 113 or not. When the data is written in the memory 113, the logical disk writing/reading means 112 reads the data and transfers the data to the upper-rank unit 100. When the data is not written in the memory 113, the logical disk writing/reading means 112 reports a reading error to the upper-rank unit 100.

The memory 113 writes data transferred from the logical disk writing/reading means 112. Then, the memory 113 reads data reading of which is commanded by the logical disk writing/reading means 112 and sends the data to the logical disk writing/reading means 112. The memory 113 is a portion where data whose writing at a defective medium portion of the HDD 130E (a medium error at a specific address portion (logical address 140A in this case) has failed is temporarily saved. In this respect, the memory 113 needs to have a buffer size of several tens of KB to several hundred KB. The memory 113 holds the data until the written data is read from the logical disk writing/reading means 112 and written in the logical disk 120.

The logical disk 120 has a plurality of HDDs (in this example, there are five HDDs 130A to 130E). The logical disk 120 has a redundancy structure and RAID 1/3/5 or the like is used as a RAID. When the logical disk 120 receives a data write command from the controller 110, data is written with redundancy at a logical address designated by the controller 110. In this example, it is illustrated that data is written at a logical address 140A. When the logical disk 120 receives a data read command from the controller 110, data is read from a logical address designated by the controller 110. In this example, it is illustrated that data is read from the logical address 140A. Normally, as mentioned above, the logical disk 120 has a redundancy structure. Even when an arbitrary one of the HDD 130A to HDD 130E in the logical disk 120 fails (when a failure occurs in redundancy), data from the controller 110 can be written, or data can be read by generating data based on a parity and data from another disk and transferred to the controller 110. The logical address 140B is the address which has a failure in redundancy.

In the logical disk 120 shown in FIG. 1, the HDD 130A is undergoing data repairing after replacement of an HDD originated from a disk failure. In the HDD 130E, a medium error has occurred at the logical address 140A. Therefore, the logical address 140A is in a double failure state where two HDDs are failing. That is, there is a redundancy destruction state (failure out of redundancy) where data cannot be generated based on the parity and data from another disk. Therefore, access to the logical address 140A is disabled and no writing is possible. Likewise, data cannot be read from the logical address 140A. While only the HDD 130A is undergoing data repairing, the HDD 130E has no medium error at a logical address 140B so that both writing and reading can be performed in the HDD 130E.

In a synchronism with the operation of the upper-rank unit 100, repairing of data in the HDD 130A is carried out based on the parity data of the other HDD 130B to HDD 130E that constitute the logical disk 120. Some RAID structure is designed in such a way that a specific single HDD has the parity data.

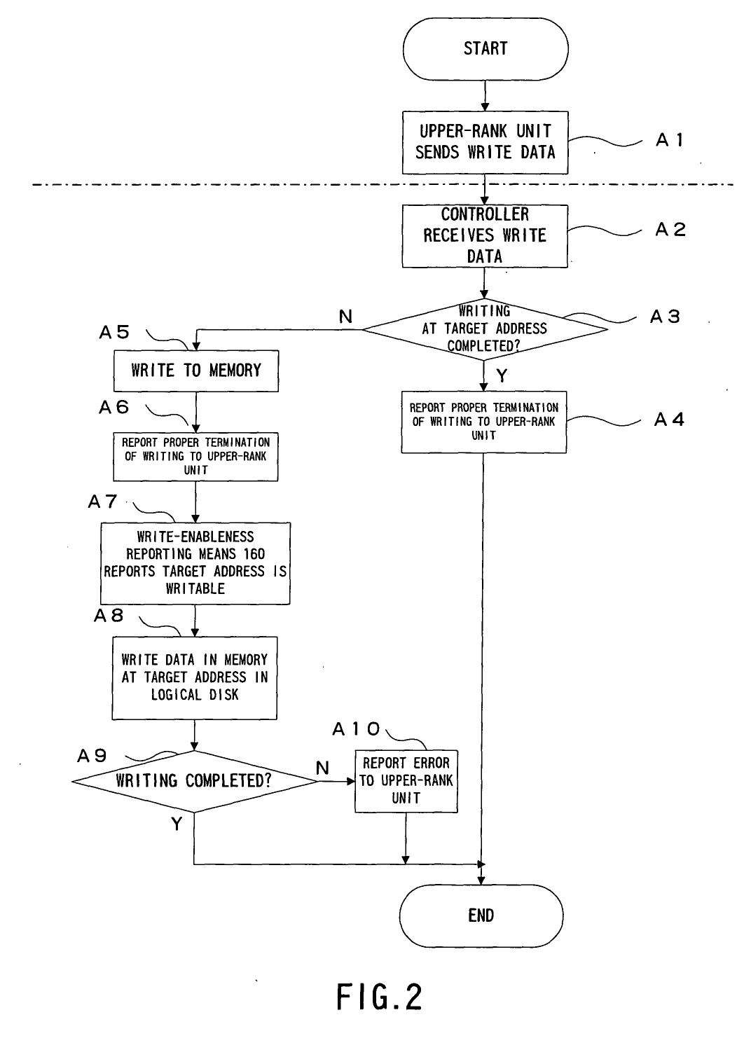

The operations of the upper-rank unit 100, the controller 110 and the logical disk 120 shown in FIG. 1 will be elaborated referring to FIGS. 1 and 2.

FIG. 2 illustrates the operations of the upper-rank unit 100, the controller 110 and the logical disk 120 according to the first embodiment of the invention. FIG. 2 is a flowchart illustrating the operations at the time the upper-rank unit 100 writes data in the logical disk 120. The flowchart differs in processes of steps A5 to A10 from the flow chart in FIG. 11 showing the upper-rank unit 100, the controller 1101 and the logical disk 120 according to the prior art. The illustrated processes according to the first embodiment of the invention can be achieved by allowing the logical disk writing/reading means 112 and the logical disk monitoring means 111 to read a program from a recording medium (magnetic disk, magnetic tape, semiconductor memory or an optical disk, such as CD-ROM, DVD (Digital Versatile Disk)) where the program is written via a reading unit. Alternatively, the processes can be achieved by downloading the program from a server or the like via a communication medium, installing the program on a recording medium (hard disk or the like not shown) of a processor (not shown) of the controller 110, reading the program onto the memory (not shown) of the processor, then running the program.

When the upper-rank unit 100 sends data to be written in the logical disk 120 to the controller 110 (step A1), the logical disk writing/reading means 112 in the controller 110 receives the write data (step A2). Next, the logical disk writing/reading means 112 writes the data at the logical address 140A in the logical disk 120 which is designated by the upper-rank unit 100. When writing is not possible then, a retry is performed a specified number of times. When writing at the logical address 140A could be done in any one of the first retry to the last one in the specified number of retries (Y in step A3), the logical disk writing/reading means 112 reports completion of proper writing to the upper-rank unit 100 and at this point of time, writing of the data from the upper-rank unit 100 is properly completed (step A4).

A description will now be given of a case where the logical disk 120 is in a double failure state where a failure has occurred in the HDD 130A and the HDD 130E as shown in FIG. 1. The logical disk 120 has a medium error at the logical address 140A in the HDD 130E and the HDD 130A is undergoing data repairing after replacement of an HDD originated from a disk failure. Because the logical address 140A is temporarily in a double failure state until data repairing and replacement of an HDD are executed at that address, therefore, no writing can be done at the address. Accordingly, writing at the logical address 140A cannot be completed even if a retry is performed a specified number of times, in which case it is determined that writing is impossible (N in step A3).

The logical disk writing/reading means 112 writes data in the memory 113 in place of the logical address 140A in the logical disk 120 and informs the write-enableness reporting means 160 of the logical address 140A writing at which could not be done (step A5). When finishing writing the data in the memory 113, the logical disk writing/reading means 112 reports proper completion of writing to the upper-rank unit 100. At this point of time, writing of the data from the upper-rank unit 100 is properly completed (step A6). When the write-enableness reporting means 160 reports thereafter that writing has become possible at the logical address 140A writing at which was not possible in step A3 to the logical disk writing/reading means 112 (step A7), the logical disk writing/reading means 112 writes the data in the memory 113 at the logical address 140A in the logical disk 120 (step A8). The memory 113 holds the retained data which should have been written at the logical address 140A at least until the logical disk writing/reading means 112 reads the data in the memory 113 and writes the data at the logical address 140A in the logical disk 120.

When the logical disk writing/reading means 112 could not complete writing at the time of writing data in the memory 113 at the logical address 140A in the logical disk 120 (N in step A9), the logical disk writing/reading means 112 reports a writing error to the upper-rank unit 100 (step A10). When writing was completed (Y in step A9), the logical disk writing/reading means 112 completes the process there.

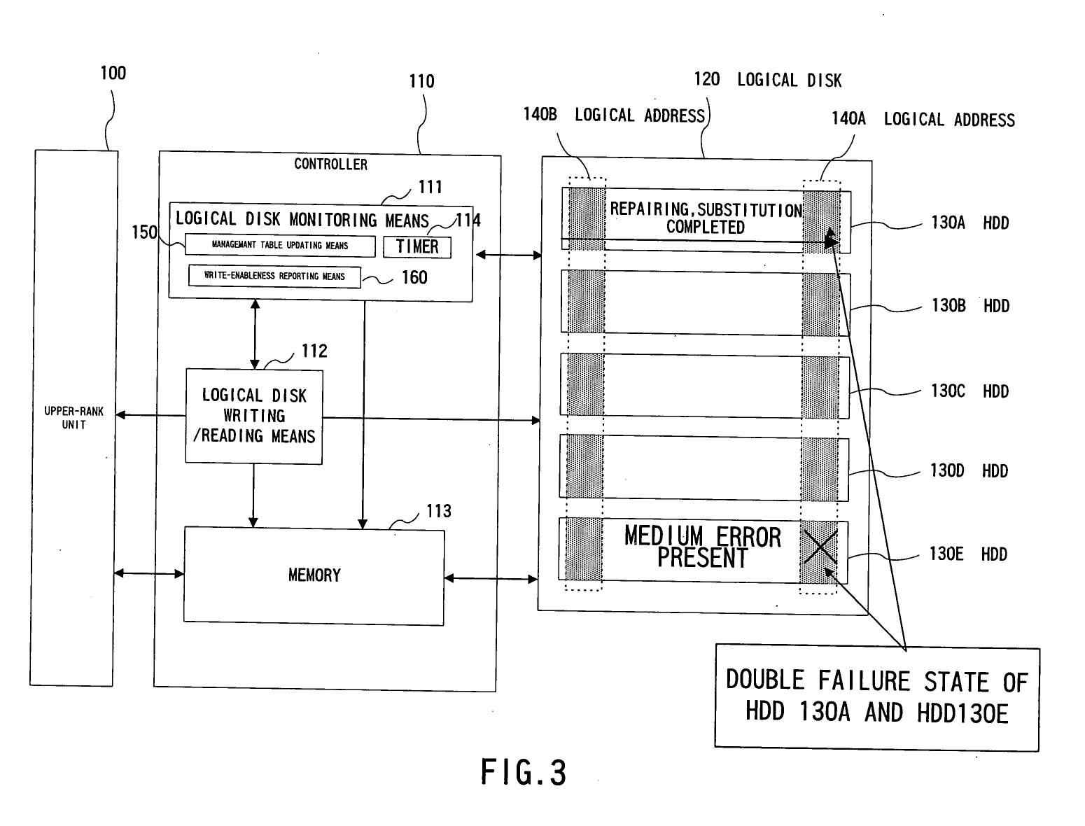

A description will now be given of FIG. 3. FIG. 3 is a diagram showing repairing of data up to the logical address 140A in the HDD 130A in the logical disk 120 which was operating in a synchronism with the operation of the upper-rank unit 100 is completed and a double failure at the logical address 140A in the HDD 130A and the HDD 130E has been eliminated. Because the logical address 140A cannot be repaired as mentioned above, the actual repairing process is skipped and writing of the data has not been performed. However, a reassigning process of moving a data area to a location other than the medium-error occurred portion is completed. That is, repairing of the logical address 140A is completed and the logical address 140A is in a state of Reassign OK (substitution OK which will be discussed later). Therefore, a double failure has been eliminated temporarily. With regard to writing of data at the logical address 140A, data writing has become possible in the embodiment so that a double failure has been eliminated surely.

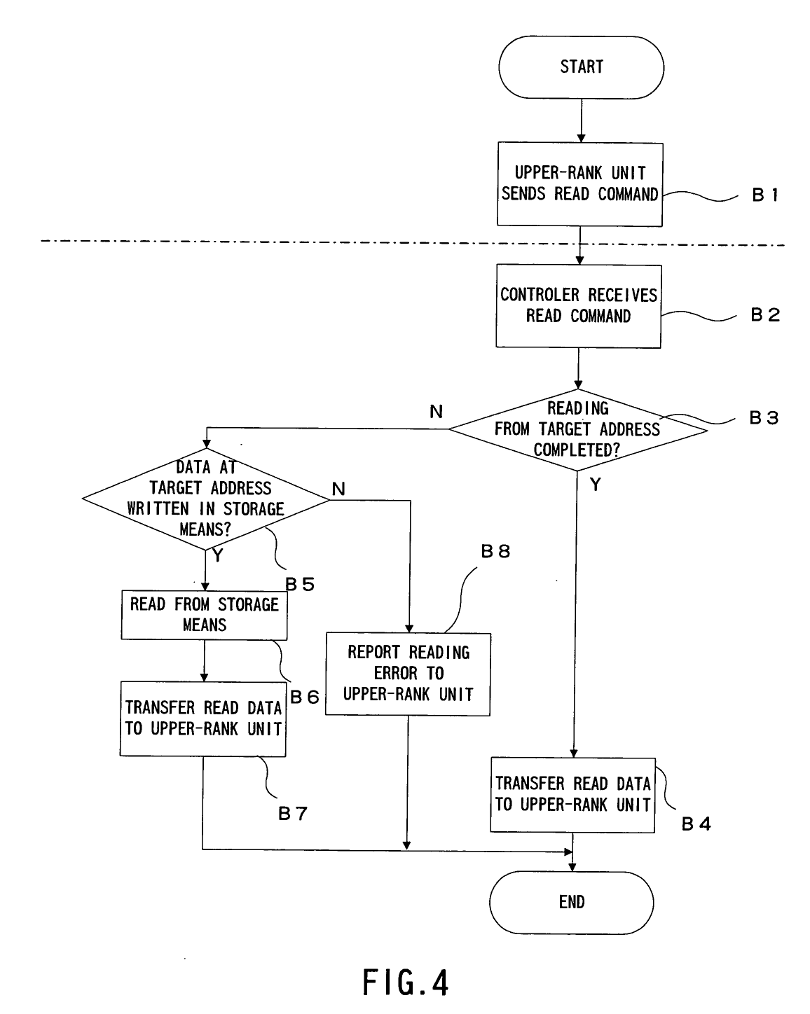

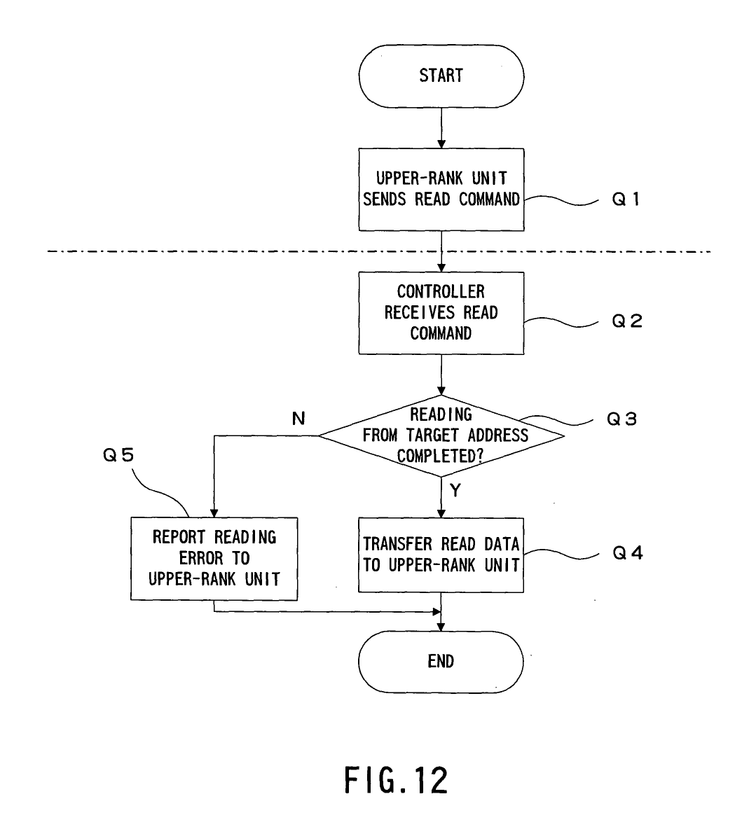

FIG. 4 is a flowchart illustrating the operations of the upper-rank unit 100, the controller 110 and the logical disk 120 at the time the upper-rank unit 100 reads data from the logical disk 120. This flow chart differs in the processes of steps B5 to B7 from the flowchart in FIG. 12 showing the operations of the upper-rank unit 100, the controller 110 and the logical disk 120 according to the prior art.

When the upper-rank unit 100 sends the controller 110 a read command to read data from the logical disk 120 (step B1), the logical disk writing/reading means 112 in the controller 110 receives the read command (step B2). Next, the logical disk writing/reading means 112 performs data reading from the logical address 140A in the logical disk 120 which is designated by the upper-rank unit 100. When reading has failed then, a retry is performed a specified number of times. When reading from the logical address 140A could be completed in any one of the first retry to the last one in the specified number of retries (Y in step B3), the logical disk writing/reading means 112 transfers the read data to the upper-rank unit 100 (step B4).

When reading from the logical address 140A could not be completed in any one of the first retry to the last one in the specified number of retries (N in step B3), the logical disk writing/reading means 112 determines whether the data is written in the memory 113 or not (step B5). When the data is written in the memory 113 (Y in step B5), the logical disk writing/reading means 112 reads the data from the memory 113 (step B6). Then, the logical disk writing/reading means 112 transfers the read data to the upper-rank unit 100 (step B7). When the data is not written in the memory 113 (N in step B5), the logical disk writing/reading means 112 reports a reading error to the upper-rank unit 100 (step B8).

The management table 151 will be discussed next. FIG. 5 is a general view of the management table 151 located in the management table updating means 150. The management table 151 shows the statuses of the individual logical addresses in the logical disk 120. The management table 151 is rewritten sequentially based on information acquired from the logical disk 120. When the write-enableness reporting means 160 reports the status of the logical disk 120 to the logical disk writing/reading means 112, the write-enableness reporting means 160 refers to the management table 151.

The horizontal items in the table 151 indicate the logical addresses in the logical disk 120. FIG. 5 shows 140A (logical address 140A) and 140B (logical address 140B) as representatives of plural logical addresses. At the logical address 140A, the HDD 130A is undergoing data repairing as shown in FIG. 1. As there is a medium error in the logical address 140A in the HDD 130E, the logical disk 120 is in a double failure state (not shown in FIG. 5).

The vertical items in the table 151 indicate the statuses of the logical disk 120. The item “1. REPAIR” indicates whether or not repairing has been completed based on parity data. When repairing has been completed, “REPAIR OK” is described. When repairing has not been completed, “REPAIR NG” is described, and when repairing has been skipped, “REPAIR SKIP” is described.

The item “2. REASSIGN DONE/UNDONE” indicates whether or not a substitute area is prepared in another location on a disk when the disk is not usable due to a medium error. “REASSIGN OK” indicates that substitution has been completed while “REASSIGNNG” indicates that substitution has not been completed.

This item is blank when the disk has no medium error occurring and substitution is not necessary.

The item “3. READ/WRITE” indicates whether reading or writing is possible or not. When reading or writing is possible, “READ OK” or “WRITE OK” is described, whereas when reading or writing is not possible, “READ NG” or “WRITE NG” is described. Specific examples at the individual logical addresses in FIG. 5 will be illustrated next.

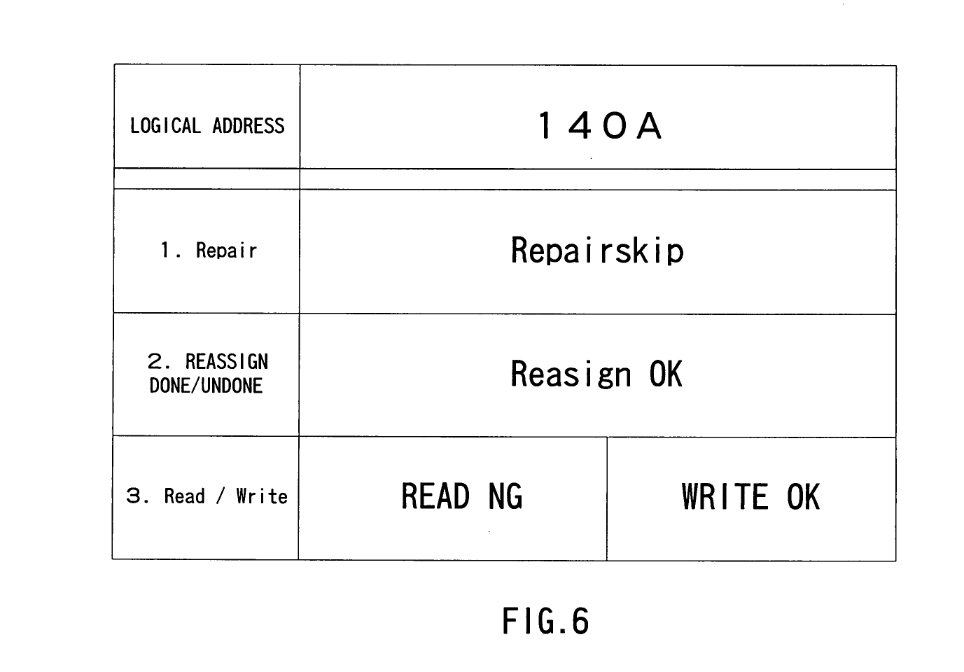

FIG. 6 is a diagram showing the details of information on the logical address 140A. First, “REPAIR SKIP” is described in the item “1. REPAIR”. This indicates that repairing could not be completed based on parity data because of the logical address 140A being in a double failure state and the logical address 140A has skipped the repairing process.

Secondly, “REASSIGN OK” is described in the item “2. REASSIGN DONE/UNDONE”. This indicates that the area at the logical address 140A in the HDD 130E is not usable due to a medium error so that a substitute area is physically prepared at another location on the disk. Because this substitute area is logically treated as the logical address 140A, data can be written with redundancy at the logical address 140A (data can be written in all of the five HDDs in the embodiment) Therefore, “REASSIGN OK” indicates that a double failure of data at the logical address 140A has been eliminated.

Thirdly, “READ NG” and “WRITE OK” are described in the item “3. READ/WRITE”. This indicates that with respect to an access from the upper-rank unit 100, the reassigning process can permit writing in the area at the logical address 140A to be done with redundancy but data could not be recovered due to a double failure so far so that the data cannot be guaranteed and cannot be read.

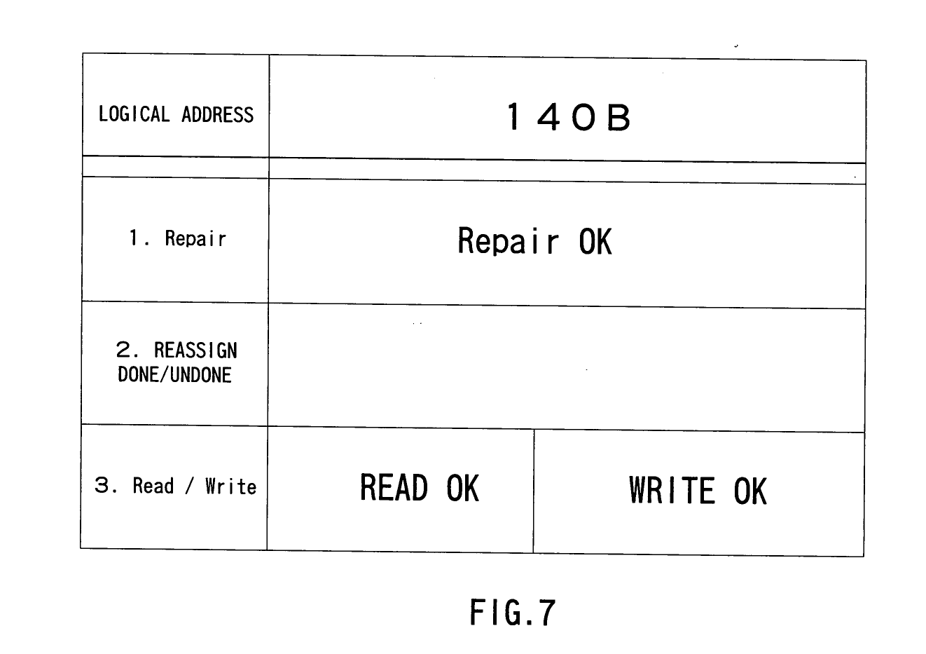

FIG. 7 is a diagram showing the details of information on the logical address 140B. First, “REPAIR OK” is described in the item “1. REPAIR”. This indicates that repairing has been completed properly at the logical address 140B based on parity data.

Secondly, there is no description in the item “2. REASSIGN DONE/UNDONE”. This is because the logical address 140B does not require a substitute area.

Thirdly, “READ OK” and “WRITE OK” are described in the item “3. READ/WRITE”. This indicates that with respect to an access from the upper-rank unit 100, writing and reading are both possible to the area at the logical address 140B.

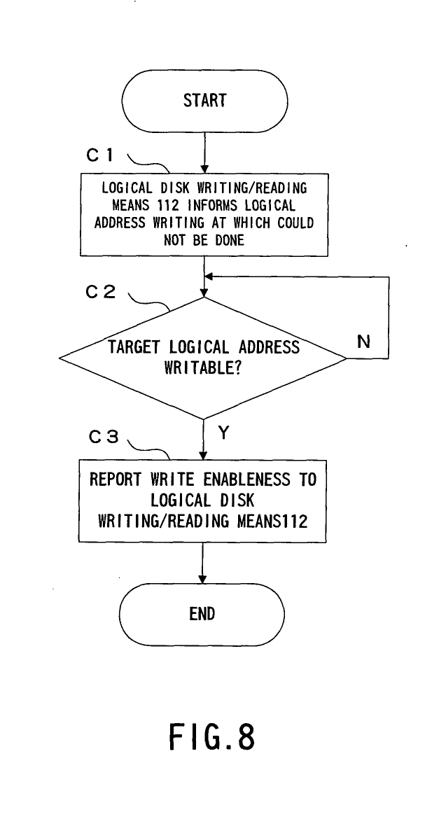

The operation of the logical disk monitoring means 111 will be discussed next. As the logical disk monitoring means 111 of the embodiment differs from that of the prior art in that the former has the write-enableness reporting means 160, the operation of the write-enableness reporting means 160 will be discussed below. FIG. 8 is a flowchart illustrating the operation of the logical disk monitoring means 111. When the logical disk writing/reading means 112 informs the write-enableness reporting means 160 of the logical address 140A at which writing in the logical disk 120 could not be done (step C1), the write-enableness reporting means 160 refers to the management table 151 and checks if “REASSIGN OK” (substitution OK or writing possible) is at the logical address 140A to check if the address is writable (step C2). When “REASSIGN OK” (substitution OK or writing possible) is the case (Y in step C2), the write-enableness reporting means 160 reports a write enableness to the logical disk writing/reading means 112 (step C3). When “REASSIGN OK” (substitution OK or writing possible) is not the case (N in step C2), the write-enableness reporting means 160 executes the operation of step C2 again.

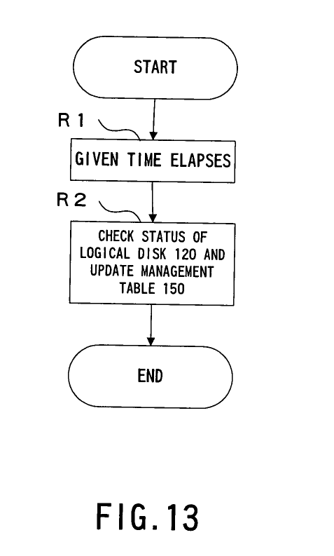

The process of step C3 corresponds to the process of step A7 in FIG. 2. As has been discussed in the foregoing description referring to FIG. 13 which is the flowchart illustrating the operation of the conventional logical disk monitoring means 111, the management table 151 is updated in a given cycle. When the item of “REASSIGN” is updated, therefore, the write-enableness reporting means 160 acknowledges that the address is writable.

According to the first embodiment, as described above, the upper-rank unit can properly complete data writing and data reading, generating no I/O error, even when a double failure occurs. This is because that when data writing at the target logical address is not possible, the data is written (or saved) in the memory and proper completion of writing is reported to the upper-rank unit. When data reading from the target logical address is not possible, the saved data is read from the memory.

The first embodiment of the invention can write data for which a write command has been issued, even when a double failure occurs. This is because when data writing at the target logical address is not possible, the data saved in the memory is written in the HDD after repairing of the logical address is completed.

It is also possible to write data in the HDD immediately after repairing of the failure-occurred logical address is completed. This is because after the data is written in the memory, it is regularly checked if the target logical address in the logical disk is writable, in a synchronism with the operation of the upper-rank unit.

The second embodiment of the invention will be described in detail referring to accompanying drawings. The foregoing description of the first embodiment of the invention has been given of the relieving method with respect to a data access when a double HDD failure has occurred due to the HDD 130A undergoing a repairing operation. With regard to the second embodiment of the invention, however, a description will be given of a relieving method with respect to a data access when a double HDD failure has occurred due to the HDD 130A being removed from the logical disk 120.

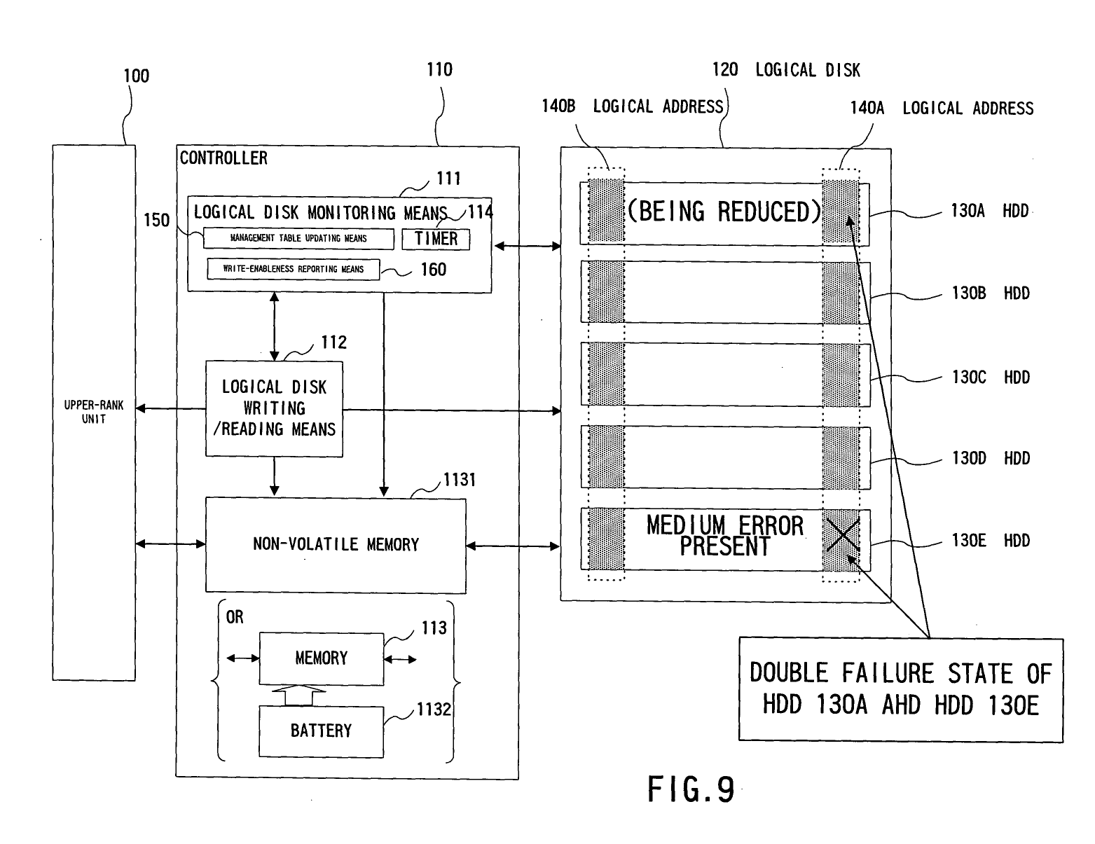

FIG. 9 is a block diagram showing the structures of an upper-rank unit 100, a controller 110 and a logical disk 120 according to the second embodiment of the invention. FIG. 9 differs from the block diagram of FIG. 1 showing the structure of the first embodiment in that the memory 113 is a non-volatile memory 1131. That is, the non-volatile memory 1131 is the memory 113 and a battery 1132 illustrated in brackets. Another difference lies in that the HDD 130A is undergoing a repairing operation in the first embodiment, whereas the HDD 130A is being removed from the logical disk 120 in the second embodiment.

The operations of the upper-rank unit 100, the controller 110 and the logical disk 120 will be elaborated referring to FIGS. 9 and 2. As the operation of the second embodiment of the invention is approximately identical to the operation of the first embodiment, the following will discuss only what the operation of the embodiment differs from the operation of the first embodiment.

When the upper-rank unit 100 sends data to be written in the logical disk 120 to the controller 110 in reduced state (step A1), the same subsequent processes as have been described in the foregoing description of the first embodiment of the invention illustrated in FIG. 2 will be performed as per the first embodiment. Because the HDD 130A that is being removed from the logical disk 120 may not be repaired immediately by a maintenance work, however, the non-volatile memory 1131 is used to avoid losing data in the memory by power cutoff or the like of the disk array apparatus. Alternatively, the memory 113 backed up by the battery 1132 is used.

According to the second embodiment of the invention, even when power is cut off when the reducing operation of the HDD has resulted in a double failure, the upper-rank unit can properly complete data writing and data reading and can read data from the target address even in reduced state and can complete writing to the HDD when repairing of the failure-occurred address is completed. This is because to avoid losing data in the memory, the non-volatile memory is used or the memory backed up by the battery is used.

With the above-described structures, the invention can allow the upper-rank unit to make a data access even when a double failure temporarily occurs in an HDD, thereby improving the reliability at the time a failure in redundancy in a logical disk occurs. Specifically, the invention has the following advantages.

The first advantage of the invention is that even when a double failure has occurred, the upper-rank unit can properly complete data writing and data reading, so that no I/O error occurs. This is because when data writing at the target logical address is not possible, the data is written (or saved) in the memory and proper completion of writing is reported to the upper-rank unit. Another reason is such that when data reading from the target logical address is not possible, data saved in the memory is read out.

The second advantage of the invention is that data for which a command to write the data can be written even when a double failure has occurred. This is because when data writing at the target logical address is not possible, the data is written in the memory. Then, the data saved in the memory is written in an HDD after repairing of the logical address is completed.

The third advantage of the invention is that data can be written in an HDD immediately after repairing of a failure-occurred logical address is completed. This is because after data is written in the memory, it is regularly checked if the target logical address in the logical disk is writable in a synchronism with the operation of the upper-rank unit, and when it is writable, data written in the memory is immediately written in the HDD.

The fourth advantage of the invention is that even when power is cut off when the reduced state of an HDD has resulted in a double failure, the upper-rank unit can properly complete data writing and data reading and can read data from the target address even during repairing of the failure-occurred address and can complete writing to the HDD when repairing of the failure-occurred address is completed. This is because the non-volatile memory is used or the memory backed up by the battery is used in order to avoid losing data in the memory.

While this invention has been described with reference to illustrative embodiments, this description is not intended to be construed in a limiting sense. Various modifications of the illustrative embodiments as well as other embodiments of the invention, will be apparent to persons skilled in the art upon reference to this description. It is, therefore, contemplated that the appended claims will cover any such modifications or embodiments as fall within the true scope of the invention.

What is claimed is:

1. A data writing apparatus for writing data into storage means, comprising:
an upper-rank unit;
first storage means where data to be written has a redundancy structure; and
a control unit which writes data in said first storage means in response to a command from said upper-rank unit and includes
second storage means, and
logical disk writing/reading means for writing in said second storage means data writing of which at an address in said first storage means is instructed by said upper-rank unit and reporting completion of writing to said upper-rank unit, when a redundancy destruction occurs at said address.

2. The data writing apparatus according to claim 1, wherein said control unit further comprises logical disk monitoring means which verifies if said redundancy destruction at said address has been recovered, and
when said logical disk monitoring means verifies that said redundancy destruction at said address has been recovered, said logical disk writing/reading means reads data written in said second storage means and writes said data at said address in said first storage means.

3. The data writing apparatus according to claim 2, wherein said logical disk monitoring means comprises:
management table updating means which checks a status of said first storage means and updates a management table;
a timer which informs said management table updating means of passage of a given time when elapsed; and
write-enableness reporting means which reports recovery of said redundancy destruction at said address to said logical disk writing/reading means when said management table indicates said recovery of said redundancy destruction.

4. The data writing apparatus according to claim 1, wherein said second storage means is non-volatile storage means or volatile storage means having an independent power supply.

5. The data writing apparatus according to claim 1, wherein said second storage means retains data written by said control unit until said data is written in said first storage means.

6. A data writing/reading apparatus for writing data into storage means, comprising:
an upper-rank unit;
first storage means where data to be written has a redundancy structure; and
a control unit which writes data in said first storage means in response to a command from said upper-rank unit and includes
second storage means, and
logical disk writing/reading means for writing in said second storage means data writing of which at an address in said first storage means is instructed by said upper-rank unit and reporting completion of writing to said upper-rank unit, when a redundancy destruction occurs at said address, and reading from said second storage means data for which a command to read from said address is given from said upper-rank unit when that data exists.

7. The data writing/reading apparatus according to claim 6, wherein said control unit further comprises logical disk monitoring means which verifies if said redundancy destruction at said address has been recovered, and
when said logical disk monitoring means verifies that said redundancy destruction at said address has been recovered, said logical disk writing/reading means reads data written in said second storage means and writes said data at said address in said first storage means.

8. The data writing/reading apparatus according to claim 7, wherein said logical disk monitoring means comprises:
management table updating means which checks a status of said first storage means and updates a management table;
a timer which informs said management table updating means of passage of a given time when elapsed; and
write-enableness reporting means which reports recovery of said redundancy destruction at said address to said logical disk writing/reading means when said management table indicates said recovery of said redundancy destruction.

9. The data writing/reading apparatus according to claim 6, wherein said second storage means is non-volatile storage means or volatile storage means having an independent power supply.

10. The data writing/reading apparatus according to claim 6, wherein said second storage means retains data written by said control unit until said data is read by said control unit.

11. A data writing apparatus for writing data into storage means, comprising:
an upper-rank unit;
first storage means including data writing of which is instructed by an upper-rank unit and redundancy data and capable of, if data of a size equal to or smaller than a size of said redundancy data is destroyed, ensuring data writing from remaining data while repairing said data writing of which is instructed, in response to a command from said upper-rank unit;
a control unit which writes data in said first storage means in response to a command from said upper-rank unit and includes
second storage means, and
logical disk writing/reading means for writing in said second storage means data for which a command to write at an address in said first storage means is given from said upper-rank unit and reporting completion of writing to said upper-rank unit, when writing is not possible due to an error during data correction in an area including said address.

12. A method for writing data into storage means where data to be written has a redundancy structure, comprising the steps of:
A) when a redundancy destruction occurs at an address in said first storage means where data to be written has a redundancy structure, writing in said second storage means data writing of which at said address is instructed by an upper-rank unit; and
B) reporting completion of writing to said upper-rank unit.

13. The method according to claim 12, further comprising the steps of:
C) verifying if said redundancy destruction at said address has been recovered;
D) when recovery of said redundancy destruction is verified, reading data written in said second storage means; and
E) writing said data at said address in said first storage means.

14. The method according to claim 12, further comprising the steps of:
F) checking a status of said first storage means when a given time elapses;
G) updating a management table;
H) reading data written in said second storage means when said management table indicates recovery of said redundancy destruction; and
I) writing said data at said address in said first storage means.

15. A method for writing and reading data into and from storage means where data to be written has a redundancy structure, comprising the steps of:
J) when a redundancy destruction occurs at an address in said first storage means, writing in said second storage means data writing of which at said address is instructed by an upper-rank unit;
K) reporting completion of writing to said upper-rank unit; and
L) when there is data reading of which from said address is instructed by said upper-rank unit, reading said data from said second storage means.

16. The method according to claim 15, further comprising the steps of:
M) when recovery of said redundancy destruction is verified, reading data written in said second storage means and writing said data at said address in said first storage means.

17. The method according to claim 15, further comprising the steps of:
N) checking a status of said first storage means when a given time elapses;
O) updating a management table;
P) reading data written in said second storage means when said management table indicates recovery of said redundancy destruction; and
Q) writing said data at said address in said first storage means.

18. A computer program capable of running on a computer so that the computer performs said steps of claim 12.
